(19) United States
(12) Patent Application Publication
(10) Pub. No.: US 2025/0296775 A1
(43) Pub. Date: Sep. 25, 2025

(54) CONTINUOUS CASSETTE SUPPLY APPARATUS

(71) Applicant: HANWHA SOLUTIONS CORPORATION, Seoul (KR)

(72) Inventors: Jong Won LEE, Seoul (KR); Seung Jin KIM, Seoul (KR); Hyun Seok JUNG, Seoul (KR); Yong Ho CHOI, Seoul (KR)

(73) Assignee: HANWHA SOLUTIONS CORPORATION, Seoul (KR)

(21) Appl. No.: 19/086,316

(22) Filed: Mar. 21, 2025

(30) Foreign Application Priority Data
Mar. 22, 2024 (KR) 10-2024-0039784

(51) Int. Cl. B65G 1/06; B65G 43/08; H01L 21/677

(52) U.S. Cl. CPC B65G 1/06; B65G 43/08; B65G 2201/0297; B65G 2203/0233; H01L 21/67766

(57) ABSTRACT

The present invention relates to a continuous cassette supply apparatus including a first transport module provided to grip one end of a first cassette having a plurality of substrates mounted therein and move in a first direction from a first set location, a second transport module provided to grip the other end of the first cassette that is moved by the first transport module and move toward a second set location in the first direction, and a frame module on which the first transport module and the second transport module are mounted and that movably supports each transport module, and the first transport module grips one end of a second cassette having a plurality of new substrates mounted therein and moves to the first location before all the substrates are extracted from the first cassette transferred to the second transport module.

### CROSS-REFERENCE TO RELATED APPLICATION

The present application claims priority and the benefit of Korean Patent Application No. 10-2024-0039784, filed on Mar. 22, 2024 in the Korean Intellectual Property Office, the entire disclosure of which is incorporated herein by reference.

### BACKGROUND

### 1. Field of the Invention

The present invention relates to a continuous cassette supply apparatus, and more specifically, to a continuous cassette supply apparatus capable of continuously supplying cassettes in which a plurality of substrates are mounted.

### 2. Discussion of Related Art

Generally, a cassette supply apparatus is installed to continuously supply a plurality of substrates to the next process.

In such a conventional cassette supply apparatus, a substrate transport module continuously grips and extracts substrates one by one from a cassette and transports the substrates to the next process, and in this case, a time for the substrate transport module to transport the substrates and a time to perform cassette replacement after all the substrates are extracted from the cassette act as factors that increase a cycle time of an entire system.

Therefore, in order to reduce the cycle time, an improvement technology for increasing the number of substrate transport modules, increasing the number of substrates mounted inside a cassette, or providing a tray on which a plurality of cassettes are mounted has been proposed, but the technology increases a size of an entire system and has the limitation in that the technology cannot be applied in places where an installation area is limited.

### SUMMARY OF THE INVENTION

The present invention has been made to solve such problems, and is directed to providing a continuous cassette supply apparatus capable of continuously supplying substrates even in places where installation space is limited, by being configured to continuously supply and discharge cassettes in which a plurality of substrates are mounted.

Objects of the present invention are not limited to the above-mentioned object, and other objects that have not been mentioned can be clearly understood by those skilled in the art from the description below.

According to an aspect of the present invention, there is provided a continuous cassette supply apparatus including a first transport module provided to grip one end of a first cassette having a plurality of substrates mounted therein and move in a first direction from a set first location, a second transport module provided to grip the other end of the first cassette that is being moved by the first transport module and move toward a second set location in the first direction, and a frame module on which the first transport module and the second transport module are mounted and that movably supports each transport module, wherein the first transport module grips one end of a second cassette having a plurality of new substrates mounted therein and moves to the first location before all the substrates are extracted from the first cassette being transferred to the second transport module.

The first transport module may include a first horizontal movement part configured to provide movement from a third location at which the first cassette supplied on the frame module is gripped to the first location, a first vertical movement part configured to provide movement from the first location to the second location in the first direction, and a first gripping part provided on the first vertical movement part to grip the one end of the first cassette.

The second transport module may include a second gripping part configured to receive the first cassette transferred from the first transport module and grip the other end of the first cassette, and a second vertical movement part configured to move the second gripping part to the second location.

The first vertical movement part and the second vertical movement part may move in units of pitch corresponding to a spacing between the substrate and another adjacent substrate in the first direction.

The first gripping part and the second gripping part may be disposed to overlap each other with respect to the first direction.

The first transport module may move to the third location to grip the second cassette when 40 to 60% of the substrates remain inside the first cassette.

The frame module may include an input part configured to supply a plurality of cassettes to the third location, and a collection part configured to move the cassette separated from the second grip part at the second location to a fourth location and discharge the cassette to the outside.

The frame module may include a sensor module configured to detect an extraction location of the substrate before the substrate is extracted by the separation module.

The sensor module may include a rotation part configured to provide rotation to prevent interference with the cassette while the cassette moves from the third location to the first location, a mounting part provided to be rotatable from the rotation part and having a measurement part disposed at a tip thereof, and a reciprocating transport part configured to linearly move the rotation part so that the measurement part enters and exits the second location.

Specific details of other embodiments are included in the detailed description and drawings.

### BRIEF DESCRIPTION OF THE DRAWINGS

A detailed description of preferred embodiments of the present invention to be described below, as well as the summary described above, will be better understood when read in conjunction with the accompanying drawings. For the purpose of illustration of the present invention, preferred embodiments are shown in the drawings. However, it should be understood that the present invention is not limited to the precise disposition and means that are illustrated.

FIG. 1 is a perspective view schematically illustrating a continuous cassette supply apparatus according to an embodiment of the present invention;

FIG. 2 is a front view illustrating the continuous cassette supply apparatus illustrated in FIG. 1 from the front;

FIGS. 3A and 3B are reference diagrams illustrating a state in which a sensor module detects a location of a substrate inside a cassette in the continuous cassette supply apparatus illustrated in FIG. 1;

FIGS. 4A-4C are reference diagrams schematically illustrating a state in which the substrate is extracted while the cassette moves in the continuous cassette supply apparatus illustrated in FIG. 2; and

FIGS. 5 to 9 are reference diagrams illustrating operations according to an operating order of the continuous cassette supply apparatus illustrated in FIG. 2.

### DETAILED DESCRIPTION OF EXEMPLARY EMBODIMENTS

Hereinafter, preferred embodiments of the present invention will be described in detail with reference to the accompanying drawings. The advantages and features of the present invention and methods for achieving the advantages and features will become clear by referencing the embodiments that will be described in detail later together with the accompanying drawings. However, the present invention is not limited to the embodiments that will be disclosed below, but may be implemented in various different forms, the embodiments are provided only to make the disclosure of the present invention complete and to fully inform those skilled in the art to which the present invention belongs of the scope of the invention, and the present invention is defined only by the claims. The same reference signs refer to the same components throughout the specification.

The present invention can be subject to various modifications and have several embodiments, and specific embodiments will be illustrated in the drawings and described.

However, this is not intended to limit the present invention to specific embodiments, and it should be understood to include all modifications, equivalents, and substitutions included in the spirit and technical scope of the present invention.

Terms including ordinal numbers such as “first” and “second” may be used to describe various components, but the components are not limited by the terms.

The terms are used only for the purpose of distinguishing one component from another component.

For example, a second component may be referred to as a first component, and similarly, a first component may also be referred to as a second component without departing from the scope of the present invention.

The term “and/or” includes a combination of a plurality of related items as described or any of the plurality of related items as described.

When a component is said to be “connected” or “coupled” to another component, it should be understood that the component may be directly connected or coupled to the other component, or there may be other components disposed in between.

On the other hand, when a component is said to be “directly connected” or “directly coupled” to another component, it should be understood that there are no other components disposed in between.

The terms used in the present application are used only to describe specific embodiments and are not intended to limit the present invention.

A singular expression includes a plural expression unless the context clearly indicates otherwise.

It should be understood that, in the present application, terms such as “include” and “have” are intended to designate the presence of a feature, number, step, operation, component, part, or combination thereof described in the specification, but do not preclude the possibility of the presence or addition of one or more other features, numbers, steps, operations, components, parts, or combinations thereof.

Hereinafter, embodiments will be described in detail with reference to the accompanying drawings, the same or corresponding components will be denoted by the same reference signs throughout the drawings, and redundant description thereof will be omitted.

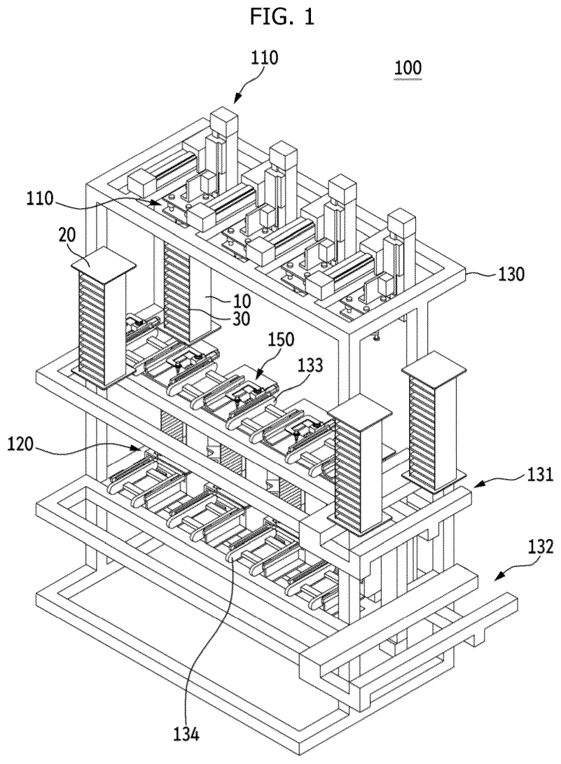

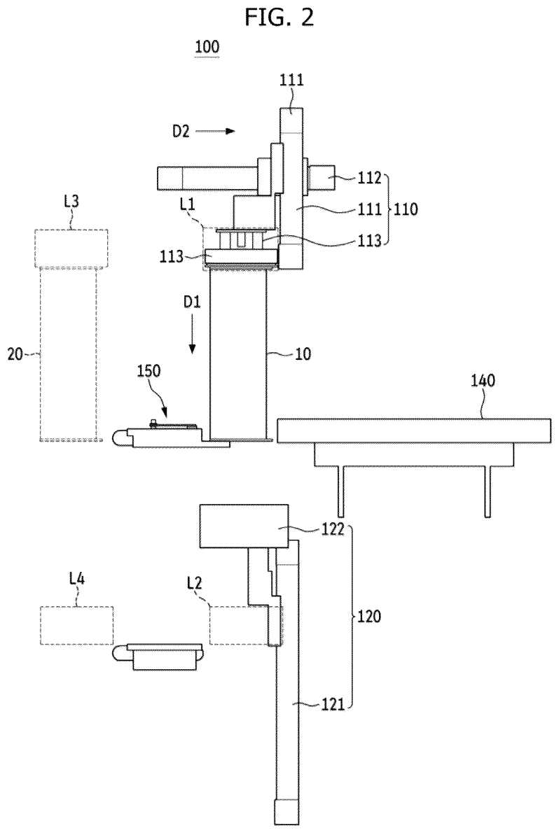

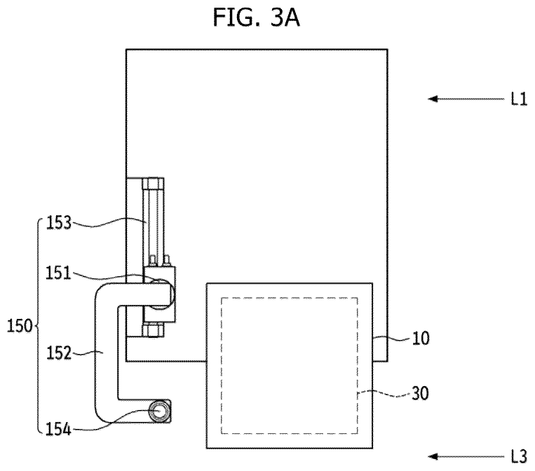

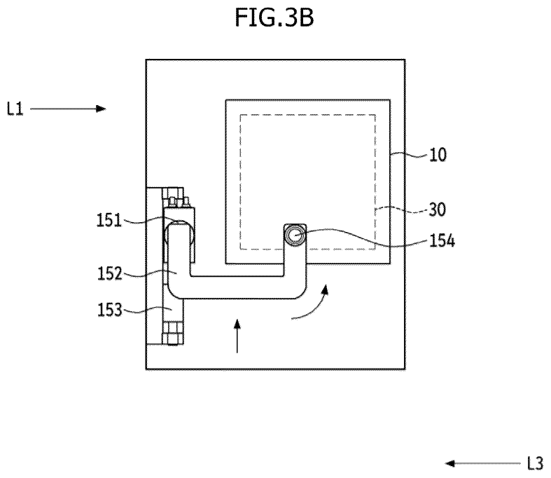

FIG. 1 is a perspective view schematically illustrating a continuous cassette supply apparatus according to an embodiment of the present invention, FIG. 2 is a front view illustrating the continuous cassette supply apparatus illustrated in FIG. 1 from the front, and FIGS. 3A and 3B are reference diagrams illustrating a state in which a sensor module detects a location of a substrate inside a cassette in the continuous cassette supply apparatus illustrated in FIG. 1.

Referring to FIGS. 1 to 3A and 3B, a continuous cassette supply apparatus 100 according to the embodiment of the present invention may include a first transport module 110, a second transport module 120, and a frame module 130.

First, the first transport module 110 may grip one end of a first cassette 10 that is supplied relatively earlier, move from a first location L1 to a second location L2 in a vertical direction, and move from a third location L3 to the first location L1 in a horizontal direction. Here, an example in which the one end of the first cassette 10 is an upper end of the first cassette 10 will be described.

The first transport module 110 may include a first vertical movement part 111, a first horizontal movement part 112, and a first gripping part 113.

Here, the first location L1 may be disposed at an upper portion in a vertical direction with respect to an installation surface, and the second location L2 may be disposed in a lower portion thereof. In this case, a direction from the first location L1 to the second location L2 is referred to as a first direction D1. Further, the third location L3 may be disposed in a horizontal direction with respect to the first location L1, and a direction from the third location L3 to the first location L1 is referred to as a second direction D2. Further, an example in which the first direction D1 and the second direction D2 are orthogonal to each other will be described, but the present invention is not limited thereto.

The first vertical movement part 111 may move the cassette from the first location L1 to the second location L2 in the first direction D1. In this case, the cassette may be installed so that the cassette can be moved from the first vertical movement part 111 by the first gripping part 113 to be described later. It is apparent that the first transport module 110 transfers the first cassette 10 to the second transport module 120 midway instead of moving to the second location L2, and the first cassette 10 moves to the second location L2 via the second transport module 120.

Further, the first horizontal movement part 112 may move the first vertical movement part 111 between the first location L1 and the third location L3. At the third location L3, new cassettes supplied on the frame module 130 to be described later may be positioned.

Further, the first gripping part 113 may be fixed to the first vertical movement part 111 while gripping the upper end of the first cassette 10.

Therefore, the newly supplied first cassette 10 is fixed at the third location L3 by the first gripping part 113, moved to the first location L1 by the first horizontal movement part 112, and then moved in the first direction D1 by the first vertical movement part 111.

Further, the second transport module 120 may grip the other end of the first cassette 10, move toward the second location L2 in the vertical direction, and move from the second location L2 to the fourth location L4 in the horizontal direction. Here, the other end of the first cassette 10 may be a lower end of the first cassette 10.

The second transport module 120 may include a second vertical movement part 121 and a second gripping part 122.

The second vertical movement part 121 may receive the first cassette 10 transferred from the first vertical movement part 111 and move toward the second location L2 while gripping the first cassette 10 using the second gripping part 122.

Here, the first vertical movement part 111 and the second vertical movement part 121 may move stepwise in units of pitch P corresponding to a spacing between one substrate and another adjacent substrate, which are disposed in a vertical direction, when vertically moving down in the first direction D1. When the first vertical movement part 111 and the second vertical movement part 121 move down stepwise in units of pitch P in this way, the substrates may be extracted one by one by a separation module 140. Here, the separation module 140 may extract one substrate 30 inside the cassette and then transfer the substrate 30 to the next process.

Further, the first vertical movement part 111 and the second vertical movement part 121 or the first gripping part 113 and the second gripping part 122 may be disposed to overlap each other with respect to the first direction D1.

After the first cassette 10 is transferred from the first transport module 110 to the second transport module 120, the first gripping part 113 in the first transport module 110 may move to the third location L3 again, grip the second cassette 20 on which a plurality of new substrates are mounted, and move to the first location L1. In this case, it is preferable for the first transport module 110 to move the second cassette 20 to the first location L1 before all the substrates 30 inside the first cassette 10 being transferred to the second transport module 120 are extracted. It is apparent that the second cassette 20 may move down in units of pitch P in the first direction D1 from the first location L1 in response to the first cassette 10 moving down in units of pitch P, so that the lowest substrate 30 is positioned at a horizontal location with respect to the separation module 140, thereby allowing the first cassette 10 to be separated and discharged and the substrates of the second cassette 20 to be continuously supplied immediately.

The frame module 130 may have the first transport modules 110 and the second transport modules 120 mounted thereon and support the first transport module 110 and the second transport module 120 so that the first transport module 110 and the second transport module 120 can move relative to each other. In the present embodiment, as illustrated in FIG. 1, for example, four first transport modules 110 and four second transport modules 120 are installed on the frame module 130, and the number of the transport modules is not limited thereto.

Further, the frame module 130 may include an input part 131 and a collection part 132.

The input part 131 may be disposed relatively higher to supply a plurality of cassettes to the third location L3.

Further, the collection part 132 may be disposed relatively lower with respect to the input part 131 and may move the cassette separated from the second gripping part 122 at the second location L2 to the fourth location L4 in a horizontal direction and discharge the cassette to the outside.

Further, the frame module 130 may be provided with an upper conveyor structure 133 for moving the cassette from the third location L3 to the first location L1 and a lower conveyor structure 134 for moving the cassette from the second location L2 to the fourth location L4.

Further, the frame module 130 may include a sensor module 150.

The sensor module 150 may include a rotation part 151, a mounting part 152, and a reciprocating transport part 153 to detect locations of the substrates inside the cassette.

The rotation part 151 may rotate the mounting part 152. For example, the rotation part 151 may selectively rotate the mounting part 152 so that the mounting part 152 and the first cassette 10 do not interfere with each other while the first cassette 10 is moving from the third location L3 to the first location L1. The rotation part 151 may operate to avoid the first cassette 10 only when the first cassette 10 moves from the third location L3 to the first location L1.

Further, the mounting part 152 may have one end rotatably coupled to the rotation part 151 and the other end provided with a measurement part 154. For example, the mounting part 152 may be bent in an approximate “L” shape and disposed so that the other end can enter and exit an internal area of the first cassette 10.

Further, the reciprocating transport part 153 may move the rotation part 151 in a straight line so that the measurement part 154 can enter and exit the inside of the first cassette 10. For example, when the first cassette 10 moves from the third location L3 to the first location L1 and then moves from the first location L1 to the second location L2, the reciprocating transport part 153 may cause the measurement part 154 to enter the first cassette 10 after the first cassette 10 moves down in units of pitch and then return the measurement part 154 inside the first cassette 10 to the outside before the separation module 140 enters the first cassette 10 after the location of the substrate 30 is ascertained.

Therefore, the sensor module 150 may confirm whether the substrate is at a discharge location inside the cassette and may also perform measurement to determine whether there are remaining substrates. For example, when the first cassette 10 moves down by one pitch unit, but the sensor module 150 measures that there is no substrate at the discharge location due to damage, the sensor module 150 may transfer a movement-down signal to move the first cassette 10 down one pitch unit before the separation module 140 moves to extract the substrates.

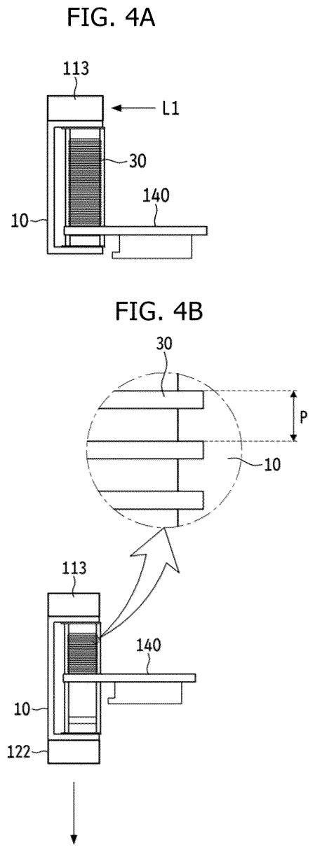

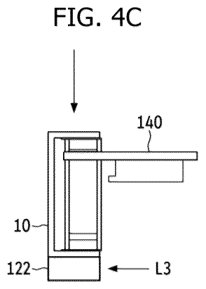

FIGS. 4A-4C are reference diagrams schematically illustrating a state in which the substrate is extracted when the cassette is moved in the continuous cassette supply apparatus illustrated in FIG. 2.

FIG. 4A shows a state in which the lowest substrate 30 is extracted by the separation module 140 in a state in which the first cassette 10 is fully loaded with substrates (or a set number of substrates).

In this case, the first cassette 10 may be moved down from the first location L1 in a state in which the first cassette 10 is gripped by the first gripping part 113 and may be moved down stepwise in units of pitch P by the first vertical movement part 111.

FIG. 4B shows a state in which some of the lower substrates 30 inside the first cassette 10 are extracted, the upper portion of the first cassette 10 is gripped by the first gripping part 113, and the lower portion of the first cassette 10 is gripped by the second gripping part 122.

In this case, when the second gripping part 122 completes gripping the lower end of the first cassette 10, the first gripping part 113 may release its grip on the upper end of the first cassette 10 and move to grip a new second cassette 20. For example, a point in time when the first gripping part 113 is separated from the upper end of the first cassette 10 is preferably a point in time when about 80% or less of the substrates remain inside the first cassette 10.

FIG. 4C shows that the second gripping part 122 moves down while gripping the lower end of the first cassette 10, and when there are no remaining substrates inside the first cassette 10, the first cassette 10 may be detached from the second gripping part 122 and discharged toward the collection part (see 132 in FIG. 1).

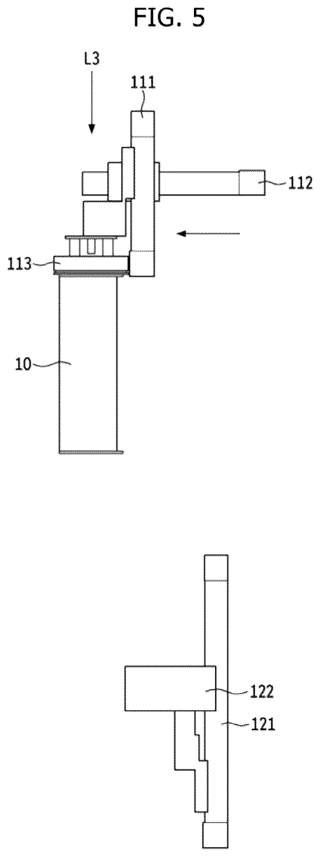

FIGS. 5 to 9 are reference diagrams showing an operation according to an operating order of the continuous cassette supply apparatus illustrated in FIG. 2. Hereinafter, the operating order of the continuous cassette supply apparatus will be described with reference to FIGS. 5 to 9.

Referring to FIG. 5, the first vertical movement part 111 moves to the third location L3 on the first horizontal movement part 112 and grips the first cassette 10 via the first gripping part 113.

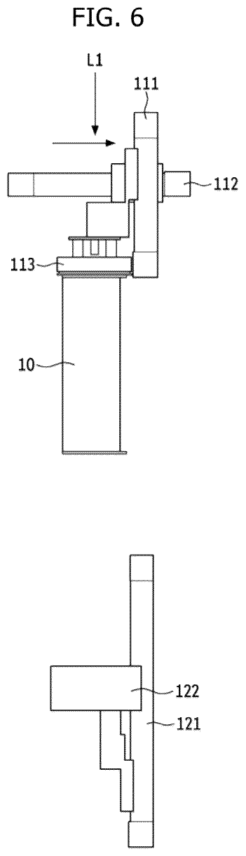

Referring to FIG. 6, the first vertical movement part 111 moves to the first location L1 on the first horizontal movement part 112 while gripping the first cassette 10.

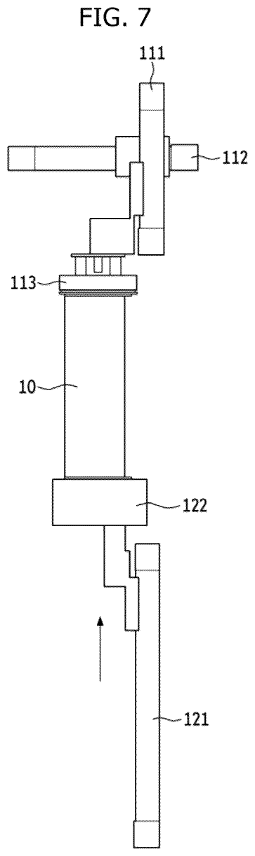

Referring to FIG. 7, when the first vertical movement part 111 moves down in units of pitch, the second vertical movement part 121 moves up to grip the first cassette 10.

When the second vertical movement part 121 reaches the lower end of the first cassette 10, the second gripping part 122 grips the lower end of the first cassette 10, and the first gripping part 113 may be separated from the upper end of the first cassette 10.

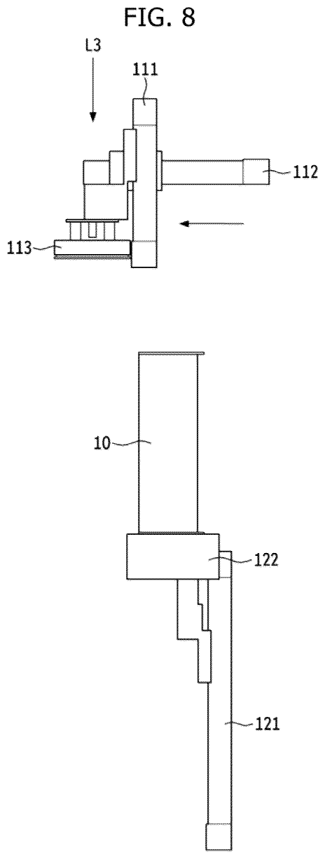

Referring to FIG. 8, when the second vertical movement part 121 moves down in units of pitch and the substrates of the first cassette 10 are separated one by one, the first vertical movement part 111 moves up to the first location L1 and then moves to the third location L3 via the first horizontal movement part 112.

In this case, the first cassette 10 may be transferred from the first vertical movement part 111 to the second vertical movement part 121 in a state in which about 80% or less of the substrates remain within the first cassette 10. It is apparent that the first vertical movement part 111 may transfer the first cassette 10 to the second vertical movement part 121 and move to the third location L3 to grip a new second cassette 20.

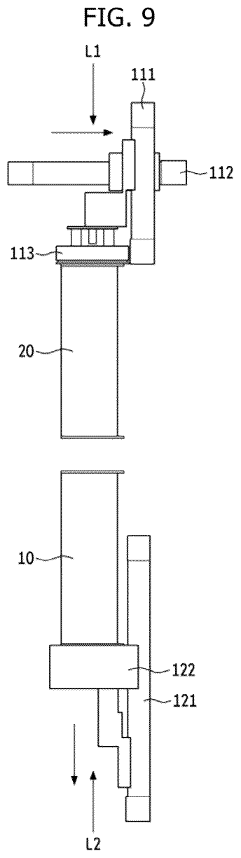

Referring to FIG. 9, the first vertical movement part 111 may grip the new second cassette 20 and move to the first location L1 in a state in which the first cassette 10 moves down stepwise on the second vertical movement part 121.

The second cassette 20 that has reached the first location L1 may start to move down in units of pitch again so that the substrates of the second cassette 20 can be supplied to the separation module 140 as soon as all the substrates are extracted from the first cassette 10.

Therefore, with the continuous cassette supply apparatus according to the embodiment of the present invention, there is an effect that it is possible to prepare the second cassette with a set number of substrates before all the substrates are extracted from the first cassette, thereby reducing the cycle time, there is no need to secure additional installation space since the additional installation space is not required due to vertical disposition of the first transport module and the second transport module, and the present invention can be easily applied to other cassette supply apparatuses since installation space is not limited.

Although not illustrated in the drawing, the substrate according to the present embodiment may be a substrate for manufacture of solar cells. For example, the substrate according to the present embodiment may be a substrate for manufacture of tandem solar cells, and the continuous cassette supply apparatus according to the present embodiment may be an apparatus that can continuously supply the substrates disposed in the cassette by supplying and collecting the cassettes in a timely manner.

In brief, the tandem solar cell (not illustrated) may include a plurality of solar cells. For example, the tandem solar cell may include a first solar cell and a second solar cell disposed on the first solar cell.

The first solar cell may include any one of a variety of solar cells, such as a crystalline silicon (Si) solar cell, a polycrystalline silicon solar cell, a CIGS-based solar cell, a gallium arsenide (GaAs) solar cell, a dye sensitized solar cell, an organic solar cell, and a compound solar cell.

The second solar cell may include a perovskite solar cell. The second solar cell may include a recombination layer, a hole transport layer, a perovskite light absorption layer, a buffer layer, an electron transport layer, and an upper electrode layer.

The recombination layer (not illustrated) may be a layer that induces recombination of electrons and holes generated in at least one of the first solar cell and the perovskite light absorption layer.

The perovskite light absorption layer may be disposed on the recombination layer. The perovskite light absorption layer may be a light absorption layer and may include a perovskite material.

The upper electrode layer may be disposed on the perovskite light absorption layer. The upper electrode layer may be an area on which light is incident and may include a transparent conductive material.

The hole transport layer may be disposed between the recombination layer and the perovskite light absorption layer. The hole transport layer may be a layer that transports holes formed in the perovskite light absorption layer and blocks the movement of electrons.

The electron transport layer may be disposed between the perovskite light absorption layer and the upper electrode layer. The electron transport layer may be a layer that transports electrons formed in the perovskite light absorption layer and blocks holes.

The buffer layer may be disposed on the perovskite light absorption layer. Specifically, the buffer layer may be disposed between the perovskite light absorption layer and the electron transport layer. The buffer layer can protect the perovskite light absorption layer from moisture, heat, and the like. Further, the buffer layer may serve as an electrical buffer between the perovskite light absorption layer and the electron transport layer.

In one embodiment, the continuous cassette supply apparatus 100 may be an apparatus that supplies the substrates 30 to a process for forming at least one layer included in the second solar cell. For example, the continuous cassette supply apparatus 100 may be an apparatus that supplies the substrates to a process area for forming the buffer layer on the substrate 30 on which a predetermined layer has been formed. Specifically, the substrate 30 on which the perovskite light absorption layer is formed may be accommodated in the cassette. Thereafter, the cassette may be provided to the continuous cassette supply apparatus 100, and the substrates 30 may be extracted one by one and transferred to the next process by the separation module 140 of the continuous cassette supply apparatus 100.

The transferred substrates 30 may be moved onto a tray by a separate transport member. The tray may include a plurality of through holes corresponding to the substrates 30. The transport member may place each of the plurality of substrates 30 in the through hole corresponding to the substrate 30. The tray may support the plurality of substrates 30 placed in the through holes.

When the plurality of substrates 30 are placed on the tray, the tray may be moved to a buffer layer formation area. For example, the tray may be transported to a physical vapor deposition device (PVD) for buffer layer formation. For example, a buffer layer formation device may be an evaporator. Afterwards, a buffer layer may be formed on the substrate. For example, a buffer layer including at least one of lithium fluoride (LiF) and a fullerene (C₆₀) may be formed on the substrate.

That is, with the continuous cassette supply apparatus 100 according to the embodiment of the present invention, it is possible to continuously supply and discharge the cassettes. Further, with the continuous cassette supply apparatus according to the embodiment, it is possible to continuously supply the substrates 30 to the aforementioned process. Accordingly, it is possible to continuously supply the substrates 30 to a subsequent process, for example, to the tray having the plurality of through holes formed therein with an effective cycle time. Further, there is an effect that there is no need to secure additional installation space since the additional installation space is not required due to vertical disposition of the first transport module and the second transport module, and the present invention can be easily applied to other cassette supply apparatuses since installation space is not limited.

With the continuous cassette supply apparatus according to the embodiment of the present invention, there is an effect that, firstly, it is possible to prepare the second cassette with a set number of substrates before all the substrates are extracted from the first cassette, thereby reducing the cycle time, secondly, there is no need to secure additional installation space since the additional installation space is not required due to vertical disposition of the first transport module and the second transport module, and thirdly, the present invention can be easily applied to other cassette supply apparatuses since installation space is not limited.

The effects of the present invention are not limited to the effects mentioned above, and other effects that are not mentioned will be clearly understood by those skilled in the art from the description of the claims.

Although specific embodiments have been illustrated and described to exemplify the technical spirit of the present invention, the present invention is not limited to the same configuration and operation as those of the specific embodiments described above, and various modifications can be implemented without departing from the scope of the present invention. Therefore, such modifications should also be considered to fall within the scope of the present invention, and the scope of the present invention should be determined by the claims below.

What is claimed is:

1. A continuous cassette supply apparatus comprising:
a first transport module provided to grip one end of a first cassette having a plurality of substrates mounted therein and move in a first direction from a first set location;
a second transport module provided to grip the other end of the first cassette that is moved by the first transport module and move toward a second set location in the first direction; and
a frame module on which the first transport module and the second transport module are mounted and that movably supports each transport module,
wherein the first transport module grips one end of a second cassette having a plurality of new substrates mounted therein and moves to the first location before all the substrates are extracted from the first cassette transferred to the second transport module.

2. The continuous cassette supply apparatus as claimed in claim 1, wherein the first transport module includes:
a first horizontal movement part configured to provide movement from a third location at which the first cassette supplied on the frame module is gripped to the first location;
a first vertical movement part configured to provide movement from the first location to the second location in the first direction; and
a first gripping part provided on the first vertical movement part to grip the one end of the first cassette.

3. The continuous cassette supply apparatus as claimed in claim 2, wherein the second transport module includes
a second gripping part configured to receive the first cassette transferred from the first transport module and grip the other end of the first cassette; and
a second vertical movement part configured to move the second gripping part to the second location.

4. The continuous cassette supply apparatus as claimed in claim 3, wherein the first vertical movement part and the second vertical movement part move in units of pitch corresponding to a spacing between one substrate and another adjacent substrate in the first direction.

5. The continuous cassette supply apparatus as claimed in claim 3, wherein the first gripping part and the second gripping part are disposed to overlap each other with respect to the first direction.

6. The continuous cassette supply apparatus as claimed in claim 2, wherein the first transport module moves to the third location to grip the second cassette when 40 to 60% of the substrates remain inside the first cassette.

7. The continuous cassette supply apparatus as claimed in claim 3, wherein the frame module includes
an input part configured to supply a plurality of cassettes to the third location; and
a collection part configured to move the cassette separated from the second grip part at the second location to a fourth location and discharge the cassette to the outside.

8. The continuous cassette supply apparatus as claimed in claim 7, wherein the frame module includes a sensor module configured to detect an extraction location of the substrate before the substrate is extracted by the separation module.

9. The continuous cassette supply apparatus as claimed in claim 8, wherein the sensor module includes:
a rotation part configured to provide rotation to prevent interference with the cassette while the cassette moves from the third location to the first location;
a mounting part provided to be rotatable from the rotation part and having a measurement part disposed at a tip thereof; and
a reciprocating transport part configured to linearly move the rotation part so that the measurement part enters and exits the second location.
